(19) United States
(12) Patent Application Publication
(10) Pub. No.: US 2018/0294207 A1
(43) Pub. Date: Oct. 11, 2018

(54) HEAT SPREADER AND THERMAL MODULE APPLYING THE HEAT SPREADER THEREOF

(71) Applicant: ASUSTeK COMPUTER INC., Taipei (TW)

(72) Inventor: Yung-Ching Huang, Taipei (TW)

(21) Appl. No.: 15/935,131

(22) Filed: Mar. 26, 2018

(30) Foreign Application Priority Data
Apr. 10, 2017 (TW) 106111943

(51) Int. Cl. H01L 23/427; H05K 7/20

(52) U.S. Cl. CPC H01L 23/427; H05K 7/20336; H05K 7/20409

(57) ABSTRACT

A heat spreader includes a first metal cover, a second metal cover, a receiving cavity, a heat conducting block, and working fluid. The receiving cavity is formed between the first metal cover and the second metal cover, the working fluid is filled in the receiving cavity. The heat conducting block is disposed in the receiving cavity and contacted with the first metal cover and the second metal cover. The heat conducting block is corresponding to a heat source contacting area of the second metal cover. A contacting area between the heat conducting block and the second metal cover is larger than the area of the heat source contacting zone of the second metal cover.

### CROSS-REFERENCE TO RELATED APPLICATION

This application claims the priority benefit of Taiwanese application serial No. 106111943, filed on Apr. 10, 2017. The entirety of the above-mentioned patent application is hereby incorporated by reference herein and made a part of specification.

### BACKGROUND OF THE INVENTION

### Field of the Invention

The invention relates to a heat spreader, and, more particularly, to a heat spreader applied in a thermal module.

### Description of the Related Art

With the progress of science and technology, electronic components become smaller and operating voltage and frequency of which becomes higher. The electronic components generate more heat, but inner heat dissipation space is reduced due to the lightness and thinness of electronic devices. Therefore, extra heat dissipation element is needed to dissipate the inner heat outside to avoid the electronic devices damaging.

### BRIEF SUMMARY OF THE INVENTION

A heat spreader is provided. The heat spreader includes a first metal cover, a second metal cover, a receiving cavity, a heat conducting block, and working fluid. The receiving cavity is formed between the first metal cover and the second metal cover. The working fluid is filled in the receiving cavity. The heat conducting block is disposed in the receiving cavity and contacted with the first metal cover and the second metal cover. The heat conducting block is corresponding to a heat source contacting area of the second metal cover, wherein a contacting area between the heat conducting block and the second metal cover is larger than the area of the heat source contacting zone of the second metal cover.

A thermal module is also provided. The thermal module includes a heat spreader, a cooling fins, and heat pipes. The heat spreader includes a first metal cover, a second metal cover, a receiving cavity, a heat conducting block, and working fluid. The receiving cavity is formed between the first metal cover and the second metal cover. The working fluid is filled in the receiving cavity. The heat conducting block is disposed in the receiving cavity and contacted with the first metal cover and the second metal cover. The heat conducting block is corresponding to a heat source contacting area of the second metal cover. A contacting area between the heat conducting block and the second metal cover is larger than the area of the heat source contacting zone of the second metal cover. Ends of the heat pipes are fixed to the first metal cover of the heat spreader. The cooling fins are assembled to the heat pipes.

The heat corresponding to the heat source contacting zone is transferred from the second metal cover to the first metal cover via the heat conducting block to be rapidly dissipated. As the heat accumulation is removed, the electronic component of the heat source or the electronic component connecting with the heat source is avoided from damaging in the high temperature and keeps the electronic component in normal operation, thus the lifespan of the electronic component is extended.

These and other features, aspects and advantages of the present invention will become better understood with regard to the following description, appended claims, and accompanying drawings.

### BRIEF DESCRIPTION OF THE DRAWINGS

FIG. 1 is schematic diagram of a heat spreader.

FIG. 2 is a partial section schematic of the heat spreader in an embodiment.

FIG. 3 is a partial section schematic of the heat spreader in an embodiment.

FIG. 4 is a partial section schematic of a heat conducting block of the heat spreader in an embodiment.

FIG. 5 is a schematic diagram of a thermal module in an embodiment.

FIG. 6 is a schematic diagram of the thermal module in an embodiment.

### DETAILED DESCRIPTION OF THE EMBODIMENTS

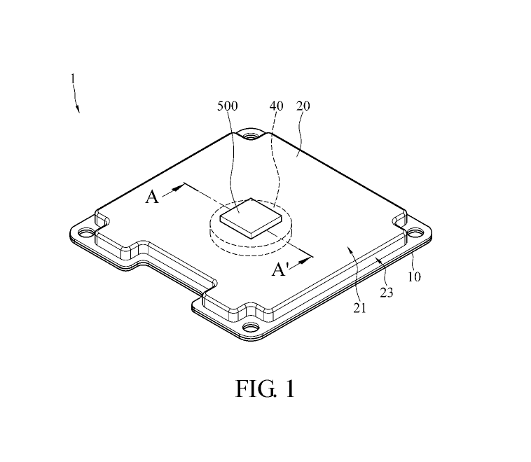

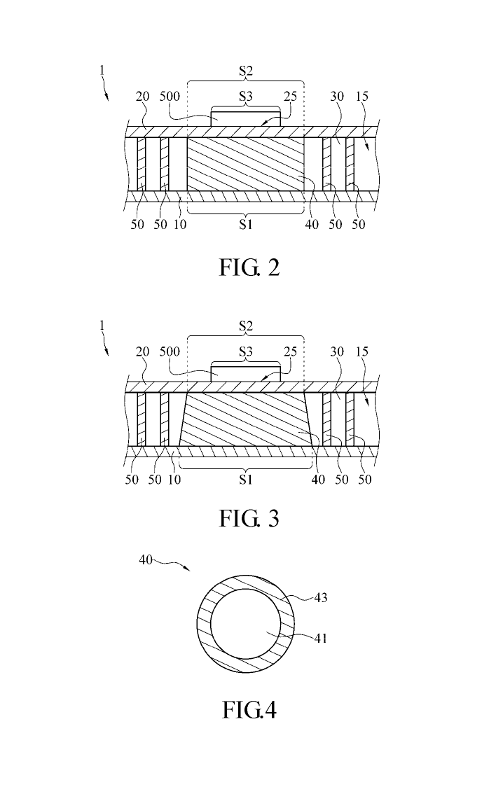

FIG. 1 is schematic diagram of a heat spreader. FIG. 2 is a partial section schematic of the heat spreader in an embodiment. FIG. 2 is a section schematic along the section line A-A′ of FIG. 1. Please refer to FIG. 1 and FIG. 2. The heat spreader 1 includes a first metal cover 10, a second metal cover 20, working fluid 30, and a heat conducting block 40. In the embodiment, the first metal cover 10 is a bottom cover, and the second metal cover 20 is an upper cover. The edge of the second metal cover 20 is connected with the edge of the first metal cover 10, and a receiving cavity 15 is formed between the first metal cover 10 and the second metal cover 20. The working fluid 30 is filled in the receiving cavity 15. The heat conducting block 40 is contacted with the first metal cover 10 and the second metal cover 20, and is disposed corresponding to a heat source contacting area 25 of the second metal cover 20.

In the embodiment, the heat source contacting zone 25 is a contacting area of the second metal cover 20 contacting with the heat source 500. A contacting area S2 between the heat conducting block 40 and the second metal cover 20 is larger than the area S3 of the heat source contacting zone 25 of the second metal cover 20. In an embodiment, the contacting area S2 between the heat conducting block 40 and the second metal cover 20 is larger than the area S3 of the heat source contacting zone 25 of the second metal cover 20. In one embodiment, the contacting area S2 between the heat conducting block 40 and the second metal cover 20 is 1.5-2 times the area S3 of the heat source contacting zone 25 of the second metal cover 20, which is not limited herein.

In the embodiment, the heat source 500 is a central processing unit (CPU), a electronic chipset, or a CPU with thermal grease.

As shown in FIG. 1, the second metal cover 20 of the heat spreader 1 has an upper surface 21 and a side surface 23. The side surface 23 is connected with the first metal cover 10, the upper surface 21 is connected with the side surface 23, and thus the second metal cover 20 and the first metal cover 10 have height difference and form a raised structure. The second metal cover 20 is formed by pressure casting in an embodiment. As shown in FIG. 1 and FIG. 2, when the second metal cover 20 is connected with the edge of the first metal cover 10, the receiving cavity 15 is formed between the second metal cover 20 and the first metal cover 10. In an embodiment, both the second metal cover 20 and the first metal cover 10 have the raised structure, or the second metal cover 20 is a plan plate and the first metal cover 10 has the raised structure in another embodiment, which is not limited herein.

As shown in FIG. 2, in an embodiment, the heat conducting block 40 is a pillar shape. Area of any cross section of the heat conducting block 40 is the same, that is to say, the contacting area S2 of the heat conducting block 40 and the second metal cover 20 is the same as the contacting area S1 of the heat conducting block 40 and the first metal cover 10. In another embodiment, as shown in FIG. 3, the heat conducting block 40 is a trapezoid with a wider top and a narrower bottom, the contacting area S2 of the heat conducting block 40 and the second metal cover 20 is not the same as the contacting area S1 of the heat conducting block 40 and the first metal cover 10. The contacting area S2 between the heat conducting block 40 and the second metal cover 20 is larger than the area S3 of the heat source contacting zone 25 of the second metal cover 20. In an embodiment, the contacting area S2 between the heat conducting block 40 and the second metal cover 20 is 1.5 to 2 times the area S3 of the heat source contacting zone 25 of the second metal cover 20, which is not limited herein. In an embodiment, the heat conducting block 40 is a trapezoid with a narrower top and a wider bottom.

In some embodiments, the heat conducting block 40 is made of metal material. For example, the heat conducting block 40 is made of at least one of copper, aluminum, silver, and alloy of the above.

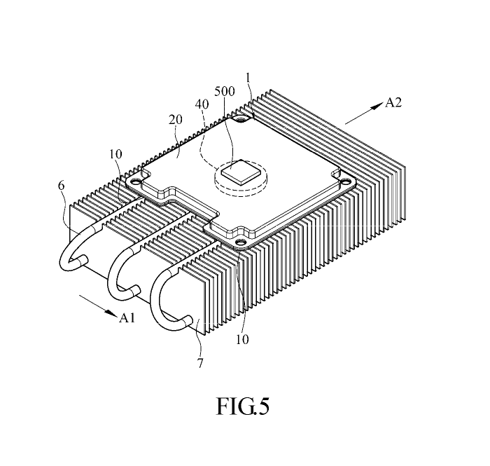

FIG. 4 is a top view of a section of a heat conducting block of the heat spreader. In an embodiment, the heat conducting block 40 is a cylinder, which is not limited herein. As shown in FIG. 4, the heat conducting block 40 is made of composite material. The center of the heat conducting block 40 is ceramic material 41, and the ceramic material 41 is covered by metal material 43 outside. The ceramic material 41 is SiC, Al₂O₃, or AlN which has high thermal conductivity and is not easy to deform in high temperature. In an embodiment, the metal material 43 is copper, aluminum, silver, or alloy of the above, which also has high thermal conductivity and is easy to be welded to the first metal cover 10 and the second metal cover 20. The heat conducting block with the two kinds of the material has supporting and heat conducting function, and is not easy to deform.

Please refer to FIG. 2 and FIG. 3. The heat spreader 1 includes a plurality of supporting pillars 50. The supporting pillars 50 are contacted with the first metal cover 10 and the second metal cover 20 to form a plurality of flow channels and the working fluid 30 flows therein. In addition, the supporting pillar 50 is a spongy structure. For example, the supporting pillar 50 is manufactured by powder metallurgy of copper powder, aluminum powder. The spongy structure provides capillarity, and thus, the working fluid 30 condenses back into liquid by contacting with the spongy structure after vaporizing into gas in the receiving cavity 15.

In the embodiment, the first metal cover 10 is welded with the heat conducting block 40, and the supporting pillars 50 are welded with the second metal cover 20. The working fluid 30 is sucked into the receiving cavity 15 of the first metal cover 10 and the second metal cover 20 by vacuum suction.

FIG. 5 is a schematic diagram of a thermal module in an embodiment. As shown in FIG. 5, the thermal module 100 includes a heat spreader 1, heat pipes 6, and cooling fins 7. The heat spreader 1 includes a first metal cover 10, a second metal cover 20, a working fluid 30 and a heat conducting block 40. In the embodiment, the first metal cover 10 is a bottom cover, and the second metal cover 20 is a top cover. The edge of the second metal cover 20 is connected with the edge of the first metal cover 10, and a receiving cavity 15 is formed between the first metal cover 10 and the second metal cover 20. The working fluid 30 is filled in the receiving cavity 15. The heat conducting block 40 is contacted with the first metal cover 10 and the second metal cover 20, and is disposed corresponding to a heat source contacting area 25 of the second metal cover 20. Please refer to FIG. 2 and FIG. 5. A heat source contacting zone 25 is a zone where the second metal cover 20 contacting with the heat source 500. In an embodiment, a contacting area S2 between the heat conducting block 40 and the second metal cover 20 is larger than the area S3 of the heat source contacting zone 25 of the second metal cover 20. A part of each heat pipe 6 is fixed to the first metal cover 10 of the heat spreader 1. The cooling fins 7 are assembled to the heat pipes 6.

In an embodiment, the heat pipes 6 connect to water source to transfer the heat of the heat pipes 6 by water cooling. The cooling fins 7 are assembled to the heat pipes 6 to increase the dissipate area. In some embodiments, as shown in FIG. 5, the heat pipes 6 is turned to extend through the cooling fins 7 and fix with the cooling fins 7, and the extending direction A1 of the cooling fins 7 is perpendicular to the extending direction A2 of the part of each heat pipe 6 extending through the cooling fins 7.

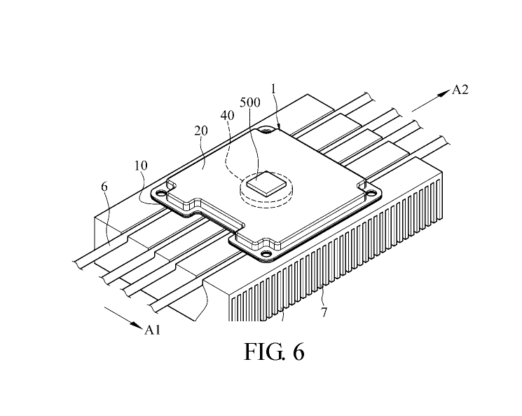

FIG. 6 is a schematic diagram of the thermal module in an embodiment. In some embodiments, a plurality of the cooling fins 7 form a cooling fin assembly 8, and a part of the heat pipes 6 are fixed in a first metal cover 10 of the heat spreader 1, and assembled in an assembling slot 81 of the cooling fin assembly 8. FIG. 5 and FIG. 6 are merely exemplary, which is not limited herein.

Attached tables 1-7 are comparing tables of measured temperatures respectively corresponding to thermal modules applying different powers of heat sources 500 with 100W, 130W, 160W, 190W, 220W, 250W, and 280W according to an embodiment and three comparing samples. In the embodiment, the heat spreader 1 includes the heat conducting block 40 as described above. The heat spreaders of the comparing sample 1, the comparing sample 2, and the comparing sample 3 do not includes the heat conducting block 40, but includes other same structures with the heat spreader in the embodiment. TC is a temperature measured from the heat source contacting zone 25 of the second metal cover 20, that is, the temperature corresponds to the temperature of the heat source 500, T1 is a temperature measured from a vertical projection zone of the heat source 500 to the first metal cover 10. In the embodiment, the contacting area S2 between the heat conducting block 40 and the second metal cover 20 is 1.5 to 2 times the area S3 of the heat source contacting zone 25 of the second metal cover 20.

As shown in table 1 to table 7, along with the increase of the power of the heat source 500, the temperature difference between the first metal cover 10 and the second metal cover 20 get increase. However, via the heat conducting block 40, the heat of the heat source 500 concentrates to the heat conducting block 40 to transfer, the temperature difference between the first metal cover 10 and the second metal cover 20 is approximately decreased from 10° C.˜30° C. to less than 5° C. Therefore, via the heat conducting block 40, the heat of the heat source 500 is rapidly transferred to the first metal cover 10, then water cooled and dissipated by the heat pipe 6 and the cooling fins 7. The temperature T1 of the first metal cover 10 of the embodiment is generally higher than the temperatures of the comparing sample 1 to the comparing sample 3, refer to table 1-3, and the difference of the water temperatures of the heat pipes 6 is not big. That is to say, the heat spreader 1 in the embodiment has more heat exchanging and higher heat transport efficiency.

Above all, the heat spreader 1 includes the heat conducting block 40 in an embodiment, and the heat conducting block 40 is contacted the first metal cover 10 and the second metal cover 20. The heat generated from the heat source 500 disposed on the heat source contacting zone 25 is transferred from the second metal cover 20 to the first metal cover 10 via the heat conducting block 40 to be rapidly dissipated. the heat spreader 1 is dissipated the heat with uniform and large area, and, furthermore, the heat conducting block 40 decrease the temperature difference between the first metal cover 10 and the second metal cover 20. Therefore, the electronic component of the heat source 500 or the electronic component connecting with the heat source 500 is avoided from damaging in the high temperature and keeps the electronic component in normal operation, thus the lifespan of the electronic component is extended.

Attached tables 1-7:

TABLE 1
(the heat source 100 W)

| | temperature | Temperature | | Water |
|---|---|---|---|---|
| | (TC) of the | (T1) of the | temperature | temperature |
| | second metal | first metal | difference | of the heat |
| | cover | cover | (TC − T1) | pipe |
| embodiment | 60.8° C. | 59° C. | 1.8° C. | 30° C. |
| comparing | 50.5° C. | 39.3° C. | 11.2° C. | 28.9° C. |
| sample 1 | | | | |
| comparing | 48.8° C. | 36.5° C. | 12.3° C. | 29.1° C. |
| sample 2 | | | | |
| comparing | 48.1° C. | 38.1° C. | 10° C. | 29° C. |
| sample 3 | | | | |

TABLE 2
(the heat source 130 W)

| | temperature | Temperature | | Water |
|---|---|---|---|---|
| | (TC) of the | (T1) of the | temperature | temperature |
| | second metal | first metal | difference | of the heat |
| | cover | cover | (TC − T1) | pipe |
| embodiment | 70.2° C. | 68° C. | 2.2° C. | 30° C. |
| comparing | 55° C. | 41.4° C. | 13.6° C. | 29.4° C. |
| sample 1 | | | | |
| comparing | 52.7° C. | 38° C. | 14.7° C. | 29.4° C. |
| sample 2 | | | | |
| comparing | 52.6° C. | 40.2° C. | 12.4° C. | 29.3° C. |
| sample 3 | | | | |

TABLE 3
(the heat source 160 W)

| | temperature | Temperature | | Water |
|---|---|---|---|---|
| | (TC) of the | (T1) of the | temperature | temperature |
| | second metal | first metal | difference | of the heat |
| | cover | cover | (TC − T1) | pipe |
| embodiment | 79.2° C. | 76.5° C. | 2.7° C. | 30° C. |
| comparing | 59.3° C. | 43.3° C. | 16° C. | 29.8° C. |
| sample 1 | | | | |
| comparing | 57.5° C. | 40° C. | 17.5° C. | 29.8° C. |
| sample 2 | | | | |
| comparing | 57.6° C. | 42.3° C. | 15.3° C. | 29.8° C. |
| sample 3 | | | | |

TABLE 4
(the heat source 190 W)

| | temperature | Temperature | | Water |
|---|---|---|---|---|
| | (TC) of the | (T1) of the | temperature | temperature |
| | second metal | first metal | difference | of the heat |
| | cover | cover | (TC − T1) | pipe |
| embodiment | 88.2° C. | 85.4° C. | 2.8° C. | 31.3° C. |
| comparing | 64° C. | 45.4° C. | 18.6° C. | 30.2° C. |
| sample 1 | | | | |
| comparing | 62.6 C. | 42.1° C. | 20.5° C. | 30.2° C. |
| sample 2 | | | | |
| comparing | 62.3° C. | 44.4° C. | 17.9° C. | 30.3° C. |
| sample 3 | | | | |

TABLE 5
(the heat source 220 W)

| | temperature | Temperature | | Water |
|---|---|---|---|---|
| | (TC) of the | (T1) of the | temperature | temperature |
| | second metal | first metal | difference | of the heat |
| | cover | cover | (TC − T1) | pipe |
| embodiment | 97.4° C. | 94.1° C. | 3.3° C. | 31.9° C. |
| comparing | 68.7° C. | 47.3° C. | 21.4° C. | 30.6° C. |
| sample 1 | | | | |
| comparing | 67.6° C. | 43.9° C. | 23.7° C. | 30.5° C. |
| sample 2 | | | | |
| comparing | 66.5° C. | 46.1° C. | 20.4° C. | 30.8° C. |
| sample 3 | | | | |

TABLE 6
(the heat source 250 W)

| | temperature | Temperature | | Water |
|---|---|---|---|---|
| | (TC) of the | (T1) of the | temperature | temperature |
| | second metal | first metal | difference | of the heat |
| | cover | cover | (TC − T1) | pipe |
| embodiment | 106.4° C. | 102.9° C. | 3.5° C. | 32.6° C. |
| comparing | 74.3° C. | 49.4° C. | 24.9° C. | 31.1° C. |
| sample 1 | | | | |
| comparing | 73.6° C. | 46.2° C. | 27.4° C. | 31.2° C. |
| sample 2 | | | | |
| comparing | 76.7° C. | 49.6° C. | 24.1° C. | 31.4° C. |
| sample 3 | | | | |

TABLE 7
(the heat source 280 W)

| | temperature | Temperature | | Water |
|---|---|---|---|---|
| | (TC) of the | (T1) of the | temperature | temperature |
| | second metal | first metal | difference | of the heat |
| | cover | cover | (TC − T1) | pipe |
| embodiment | 115.5° C. | 112° C. | 3.5° C. | 33.5° C. |
| comparing | 80.5° C. | 51.7° C. | 28.8° C. | 31.7° C. |
| sample 1 | | | | |
| comparing | 77.8° C. | 47.7° C. | 30.1° C. | 31.7° C. |
| sample 2 | | | | |
| comparing | 82.4° C. | 50.2° C. | 32.2° C. | 31.4° C. |
| sample 3 | | | | |

Although the present invention has been described in considerable detail with reference to certain preferred embodiments thereof, the disclosure is not for limiting the scope of the invention. Persons having ordinary skill in the art may make various modifications and changes without departing from the scope. Therefore, the scope of the appended claims should not be limited to the description of the preferred embodiments described above.

What is claimed is:

1. a heat spreader, comprising:
a first metal cover;
a second metal cover;
a receiving cavity, formed between the first metal cover and the second metal cover;
working fluid, filled in the receiving chamber; and
a heat conducting block, disposed in the receiving cavity, contacted with the first metal cover and the second metal cover, and corresponding to a heat source contacting area of the second metal cover, wherein a contacting area between the heat conducting block and the second metal cover is larger than the area of the heat source contacting zone of the second metal cover.

2. The heat spreader according to claim 1, wherein the contacting area of the heat conducting block and the second metal cover is not the same as the contacting area of the heat conducting block and the first metal cover.

3. The heat spreader according to claim 1, wherein the heat conducting block is copper, aluminum, silver, or alloy of the above.

4. The heat spreader according to claim 1, wherein the center of the heat conducting block is ceramic material and the ceramic material is covered by metal material.

5. The heat spreader according to claim 1, further comprising a plurality of supporting pillars, the supporting pillars contacting the first metal cover and the second metal cover to form a plurality of flow channels.

6. A thermal module, comprising:
a heat spreader, comprising:
a first metal cover;
a second metal cover;
a receiving cavity, formed between the first metal cover and the second metal cover;
working fluid, the receiving cavity; and
a heat conducting block, disposed in the receiving cavity, contacted with the first metal cover and the second metal cover, and corresponding to a heat source contacting area of the second metal cover, wherein a contacting area between the heat conducting block and the second metal cover is larger than the area of the heat source contacting zone of the second metal cover;
a plurality of heat pipes, ends of the heat pipes fixed on the first metal cover of the heat spreader; and
a plurality of the cooling fins, assembled to the heat pipe.

7. The thermal module according to claim 6, wherein the contacting area of the heat conducting block and the second metal cover is not the same as the contacting area of the heat conducting block and the first metal cover.

8. The thermal module according to claim 6, wherein the heat conducting block is copper, aluminum, silver, or alloy of the above.

9. The thermal module according to claim 6, wherein the center of the heat conducting block is ceramic material and the ceramic material is covered by metal material.
